(19) United States
(12) Patent Application Publication
(10) Pub. No.: US 2021/0027399 A1
(43) Pub. Date: Jan. 28, 2021

(54) ENERGY MANAGEMENT SYSTEM

(71) Applicant: TOYOTA JIDOSHA KABUSHIKI KAISHA, Toyota-shi (JP)

(72) Inventors: Hideshi MIZUTANI, Toyota-shi (JP); Ikuo OHTA, Toyota-shi (JP); Atsushi SAJIKI, Okazaki-shi (JP); Takao INATA, Tokyo-to (JP); Yohei TANIGAWA, Toyota-shi (JP); Atsushi NAKAJIMA, Kariya-city (JP); Atsuo KOMATSUBARA, Nagakute-shi (JP)

(21) Appl. No.: 16/923,293

(22) Filed: Jul. 8, 2020

(30) Foreign Application Priority Data
Jul. 26, 2019 (JP) 2019-137871

(51) Int. Cl. G06Q 50/06; H01M 10/42; H02J 7/00; G06Q 10/06; G01R 22/06

(52) U.S. Cl. CPC G06Q 50/06; H01M 10/425; H02J 7/0047; H01M 2010/4271; G01R 22/061; H01M 2220/10; G06Q 10/06315

(57) ABSTRACT

An energy management system capable of optimizing a distribution of energy storage between a battery and a hydrogen energy storage system is provided. An energy management system includes a collection unit configured to collect arrival and departure information and information about weather, a prediction unit configured to predict a demand fluctuation in an amount of electric power used in an airport based on the information collected by the collection unit, and a determination unit configured to determine a distribution of energy storage between a battery and a hydrogen energy storage system based on the demand fluctuation predicted by the prediction unit.

### CROSS REFERENCE TO RELATED APPLICATIONS

This application is based upon and claims the benefit of priority from Japanese patent application No. 2019-137871, filed on Jul. 26, 2019, the disclosure of which is incorporated herein in its entirety by reference.

### BACKGROUND

The present disclosure relates to an energy management system.

For the purpose of reducing greenhouse gas emissions at airports, efforts are being made to consider about how to achieve “zero emission” in which all the electric power to be consumed is supplied by renewable energy sources such as photovoltaic power generation, wind power generation, geothermal power generation, hydroelectric power generation, and biomass power generation. However, since the supply of renewable energy varies, it is essential to install an energy storage system. As an energy storage system, a hydrogen energy storage system that converts electric energy into hydrogen to be stored is known. Japanese Unexamined Patent Application Publication No. 2013-032271 discloses a technique related to a system for continuously generating hydrogen at a low cost.

### SUMMARY

There has been a study made on how to install both a battery and a hydrogen energy storage system as an energy storage system in an airport. However, sufficient consideration has not been given to the distribution of energy storage between the battery and the hydrogen energy storage system. For this reason, there is a possibility that more batteries and hydrogen energy storage systems than necessary may be installed in the airport.

The present disclosure has been made in light of the above circumstances. An object of the present disclosure is to provide an energy management system capable of optimizing a distribution of energy storage between a battery and a hydrogen energy storage system.

An example aspect of the present disclosure is an energy management system including: a collection unit configured to collect arrival and departure information and information about weather; a prediction unit configured to predict a demand fluctuation in an amount of electric power used in an airport based on the information collected by the collection unit; and a determination unit configured to determine a distribution of energy storage between a battery and a hydrogen energy storage system based on the demand fluctuation predicted by the prediction unit.

Since the distribution of energy storage between the battery and the hydrogen energy storage system is determined based on the accurate demand prediction of the amount of the electric power used in the airport, the distribution of energy storage can be optimized. This consequently prevents installation of an excessive number of batteries and hydrogen energy storage systems in the airport.

Further, the determination unit may be configured to calculate, based on the demand fluctuation predicted by the prediction unit, a first amount of electric power that can cover electric power consumption in an airport during a predetermined first period from the present time and a second amount of electric power that can cover electric power consumption in the airport during a second period from the present time, the second period being shorter than the first period, and determine the distribution of the energy storage between the battery and the hydrogen energy storage system in such a way that the second amount of the electric power is stored in the battery and that a third amount of electric power is stored in the hydrogen energy storage system, the third amount of the electric power being obtained by subtracting the second amount of the electric power from the first amount of the electric power. By determining the distribution of the energy storage between the battery and the hydrogen energy storage system in this manner, it is possible to optimize the distribution of the energy storage.

Further, the collection unit may be further configured to collect a unit energy price of a neighboring area of the airport, and the determination unit may be configured to determine, according to the unit energy price, a ratio of an amount of electric power to be supplied to the neighboring area of the airport to a surplus amount of electric power obtained by subtracting an amount of electric power actually used in the airport during the first period from a total amount of electric power stored in the battery and the hydrogen energy storage system. The profitability can be further enhanced by determining the ratio according to the unit energy price of the neighboring area in this manner.

According to the present disclosure, it is possible to optimize a distribution of energy storage between a battery and a hydrogen energy storage system.

The above and other objects, features and advantages of the present disclosure will become more fully understood from the detailed description given hereinbelow and the accompanying drawings which are given by way of illustration only, and thus are not to be considered as limiting the present disclosure.

### BRIEF DESCRIPTION OF DRAWINGS

FIG. 1 is a block diagram showing a configuration of an energy management system according to an embodiment;

FIG. 2 is a flowchart showing a processing flow of the energy management system according to the embodiment;

FIG. 3 is a schematic diagram showing an example of a demand fluctuation in an amount of electric power used in an airport during a first period from the present time, which is predicted by a prediction unit of the energy management system according to the embodiment; and

FIG. 4 is a schematic diagram for explaining a method for utilizing stored energy that is not actually used during the first period after the energy is stored in a battery and a hydrogen energy storage system.

### DESCRIPTION OF EMBODIMENTS

The present disclosure will be described below through the embodiment of the disclosure, but the disclosure according to the claims is not limited to the following embodiment. Further, not all of the configurations described in the embodiment are essential as means for solving the problem. For clarity of description, the following description and drawings are omitted and simplified as appropriate. In the drawings, the same elements are denoted by the same reference numerals, and repeated descriptions are omitted as necessary.

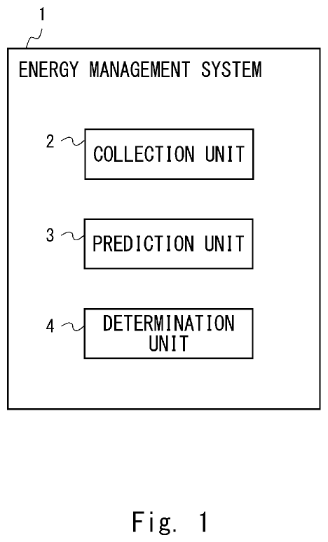

First, a configuration of an energy management system according to this embodiment will be described with reference to FIG. 1. FIG. 1 is a block diagram showing a configuration of an energy management system 1. As shown in FIG. 1, the energy management system 1 includes a collection unit 2, a prediction unit 3, and a determination unit 4.

The collection unit 2 collects arrival and departure information and information about weather. The prediction unit 3 predicts a demand fluctuation in an amount of electric power used in the airport based on information collected by the collection unit 2. The determination unit 4 determines the distribution of energy storage between the battery and the hydrogen energy storage system based on the demand fluctuation in the amount of the electric power used in the airport predicted by the prediction unit 3.

Next, a processing flow of the energy management system 1 will be described. In the following description, FIG. 1 is also referred to as appropriate.

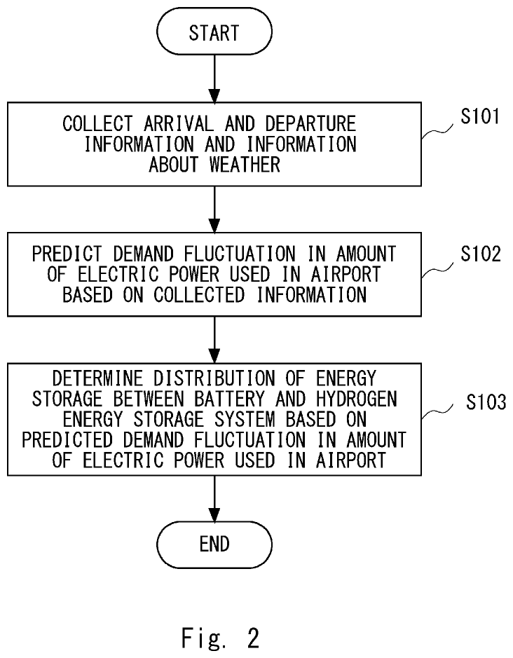

FIG. 2 is a flowchart showing the processing flow of the energy management system 1. As shown in FIG. 2, first, the collection unit 2 collects arrival and departure information and information about weather (Step S101). Next, the prediction unit 3 predicts a demand fluctuation in an amount of electric power used in the airport based on the collected information (Step S102). Next, the determination unit 4 determines the distribution of energy storage between a battery and a hydrogen energy storage system based the predicted demand fluctuation in the amount of the electric power used in the airport (Step S103).

The number of arrivals and departures at the airport and the weather included in the information collected in Step S101 are factors that have a large influence on a demand fluctuation in the amount of electric power used in the airport. In Step S102, the prediction accuracy can be improved, because the demand fluctuation in the amount of the electric power used in the airport is predicted based on the factors affecting the demand fluctuation in the amount of the electric power used in the airport. Further, in Step S103, since the distribution of energy storage between the battery and the hydrogen energy storage system is determined based on the accurate demand prediction of the amount of the electric power used in the airport, the distribution of energy storage can be optimized. This consequently prevents installation of an excessive number of batteries and hydrogen energy storage systems in the airport.

Next, the details of the method for determining the distribution of energy storage between the battery and the hydrogen energy storage system in the determination unit 4 shown in FIG. 1 based on the predicted demand fluctuation in the amount of the electric power used in the airport will be described.

The determination unit 4 calculates a first amount of electric power that can cover the electric power consumption in the airport during a predetermined first period from the present time based on the demand fluctuation in the amount of the electric power consumption in the airport predicted by the prediction unit. Here, the first period is a period expected to be required for restoration in the event of an emergency such as a power outage due to a natural disaster and is, for example, 10 days.

Further, the determination unit 4 calculates a second amount of electric power that can cover the electric power consumption in the airport during a predetermined second period from the present time. When energy is stored in the hydrogen energy storage system, it takes time to reconvert the energy into electric power. For this reason, it is necessary to store the amount of the electric power that is expected to be used in the most recent predetermined period in the battery. The most recent predetermined period is the second period. The second period is shorter than the first period and is, for example, three days.

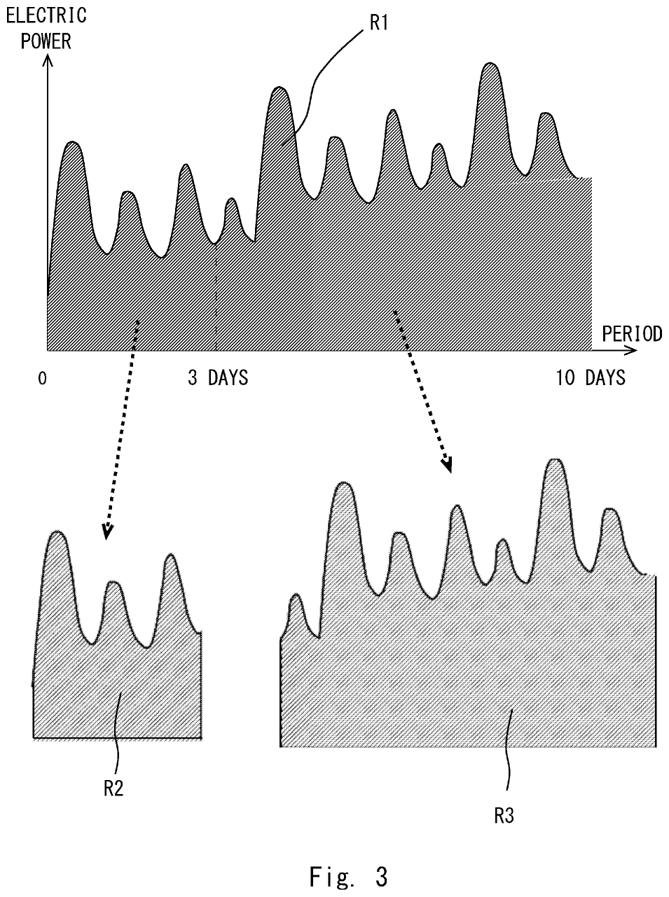

FIG. 3 is a schematic diagram showing an example of a demand fluctuation in the amount of the electric power used in the airport from the present time to the first period predicted by the prediction unit 3 (see FIG. 1). Here, the horizontal axis represents a period, and the vertical axis represents electric power. The amount of electric power is an integral of power over time. The first period is 10 days, and the second period is 3 days. As shown in FIG. 3, an amount of electric power R1 expected to be used in the airport for 10 days from the present time is the first amount of the electric power. An amount of electric power R2 that is expected to be used in 3 days from the present time is the second amount of the electric power. An amount of the electric power R3 obtained by subtracting the second amount of the electric power from the first amount of the electric power is the third amount of the electric power.

The determination unit 4 shown in FIG. 1 determines the distribution of energy storage between the battery and the hydrogen energy storage system so that the battery stores the second amount of the electric power, and the hydrogen energy storage system stores the third amount of the electric power, which is obtained by subtracting the second amount of the electric power from the first amount of the electric power. By optimizing the distribution of energy storage between the battery and the hydrogen energy storage system, it is possible to prevent installation of an excessive number of batteries and hydrogen energy storage systems in the airport.

Next, a method for utilizing the stored energy that is not actually used during the first period after the energy is stored in the battery and the hydrogen energy storage system will be described.

During the first period from the present time, the amount of the electric power used in the airport is covered entirely by the amount of the electric power in the battery and hydrogen energy storage system only when the supply of renewable energy is stopped in the event of an emergency such as a power outage due to a natural disaster. In normal times, the amount of the electric power that cannot be covered by renewable energy is supplied from the battery or the hydrogen energy storage system. For this reason, in normal times, there is stored energy that is not actually used during the first period after energy is stored in the battery and the hydrogen energy storage system.

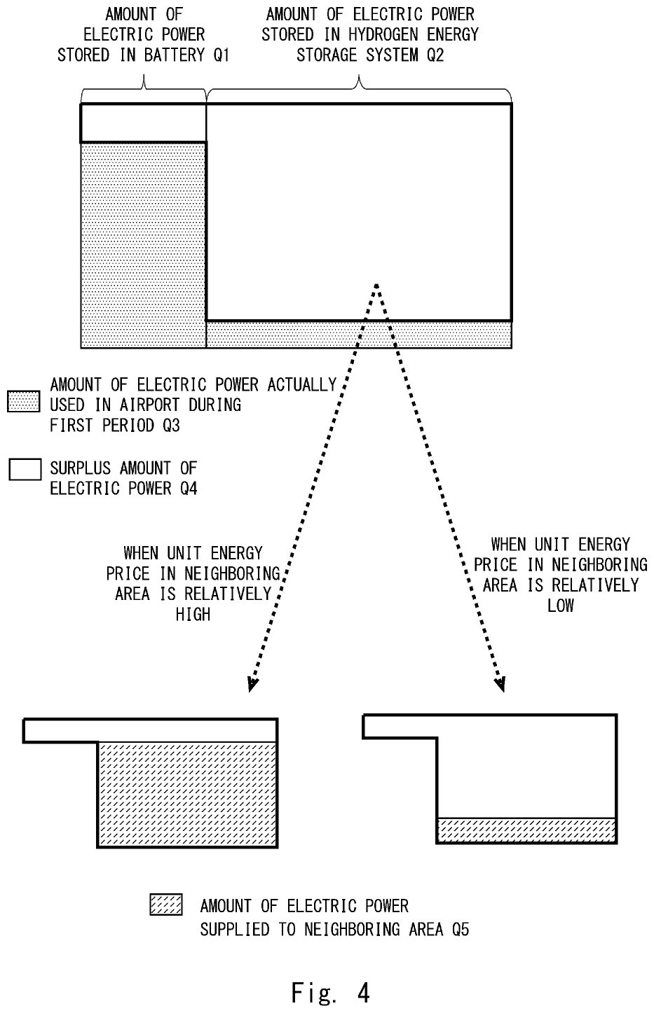

FIG. 4 is a schematic diagram for explaining a method for utilizing the stored energy that is not actually used during the first period after the energy is stored in the battery and the hydrogen energy storage system. Here, the amount of the electric power stored in the battery is represented by Q1, and the amount of the electric power stored in the hydrogen energy storage system is represented by Q2. The amount of the electric power actually used in the airport during the first period is Q3. As shown in the upper part of FIG. 4, the amount of the electric power obtained by subtracting the amount of the electric power Q3 actually used in the airport during the first period from the total amount of electric power stored in the battery and the hydrogen energy storage system (Q1+Q2) is a surplus amount of electric power Q4.

The surplus amount of the electric power Q4 may be stored in the battery or the hydrogen energy storage system, or a part of the electric power Q5 of the surplus amount of the electric power Q4 may be supplied to a neighboring area as shown in the lower part of FIG. 4. The determination unit 4 (see FIG. 1) may determine a ratio W of the amount of the electric power Q5 supplied to the neighboring area to the surplus amount of the electric power Q4 based on the unit energy price of the neighboring area. For example, the determination unit 4 determines the ratio W to be relatively high when the unit energy price in the neighboring area is relatively high, and determines the ratio W to be relatively low when the unit energy price in the neighboring area is relatively low. The profitability can be further enhanced by determining the ratio W according to the unit energy price of the neighboring area in this manner.

As described above, the energy management system 1 according to this embodiment collects the arrival and departure information and information about weather, including factors that have a large influence on a demand fluctuation in the amount of the electric power used in the airport. The prediction accuracy can be improved, because the demand fluctuation in the amount of the electric power used in the airport is predicted based on the factors affecting the demand fluctuation in the amount of the electric power used in the airport. Further, since the distribution of energy storage between the battery and the hydrogen energy storage system is determined based on the accurate demand prediction of the amount of the electric power used in the airport, the distribution of energy storage can be optimized. This consequently prevent installation of an excessive number of batteries and hydrogen energy storage systems in the airport.

Note that the present disclosure is not limited to the above-described embodiment, and may be appropriately modified without departing from the scope thereof.

For example, in the above-described embodiments, the energy management system according to the present disclosure has been described as a hardware configuration, but the present disclose is not limited thereto. In the present disclosure, any processing of the energy management system can be achieved by a processor, such as a CPU (Central Processing Unit), loading and executing a computer program stored in a memory.

The program can be stored and provided to a computer using any type of non-transitory computer readable media. Non-transitory computer readable media include any type of tangible storage media. Examples of non-transitory computer readable media include magnetic storage media (such as floppy disks, magnetic tapes, hard disk drives, etc.), optical magnetic storage media (e.g. magneto-optical disks), CD-ROM (compact disc read only memory), CD-R (compact disc recordable), CD-R/W (compact disc rewritable), and semiconductor memories (such as mask ROM, PROM (programmable ROM), EPROM (erasable PROM), flash ROM, RAM (random access memory), etc.). The program may be provided to a computer using any type of transitory computer readable media. Examples of transitory computer readable media include electric signals, optical signals, and electromagnetic waves. Transitory computer readable media can provide the program to a computer via a wired communication line (e.g. electric wires, and optical fibers) or a wireless communication line.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. An energy management system comprising:
a collection unit configured to collect arrival and departure information and information about weather;
a prediction unit configured to predict a demand fluctuation in an amount of electric power used in an airport based on the information collected by the collection unit; and
a determination unit configured to determine a distribution of energy storage between a battery and a hydrogen energy storage system based on the demand fluctuation predicted by the prediction unit.

2. The energy management system according to claim 1, wherein
the determination unit is configured to calculate, based on the demand fluctuation predicted by the prediction unit, a first amount of electric power that can cover electric power consumption in an airport during a predetermined first period from the present time and a second amount of electric power that can cover electric power consumption in the airport during a second period from the present time, the second period being shorter than the first period, and determine the distribution of the energy storage between the battery and the hydrogen energy storage system in such a way that the second amount of the electric power is stored in the battery and that a third amount of electric power is stored in the hydrogen energy storage system, the third amount of the electric power being obtained by subtracting the second amount of the electric power from the first amount of the electric power.

3. The energy management system according to claim 2, wherein
the collection unit is further configured to collect a unit energy price of a neighboring area of the airport, and
the determination unit is configured to determine, according to the unit energy price, a ratio of an amount of electric power to be supplied to the neighboring area of the airport to a surplus amount of electric power obtained by subtracting an amount of electric power actually used in the airport during the first period from a total amount of electric power stored in the battery and the hydrogen energy storage system.
